(19) United States
(12) Patent Application Publication
(10) Pub. No.: US 2009/0011127 A1
(43) Pub. Date: Jan. 8, 2009

(54) PROCESS AND APPARATUS FOR SUPERIMPOSING A LAYER OF A SEPARATING AGENT

(75) Inventor: STEPHAN KUPER, BAD HOMBURG (DE)

Correspondence Address: CANTOR COLBURN, LLP, 20 Church Street, 22nd Floor, Hartford, CT, 06103, US

(73) Assignee: LEYBOLD OPTICS GMBH, ALZENAU (DE)

(21) Appl. No.: 11/947,491

(22) Filed: Nov. 29, 2007

(30) Foreign Application Priority Data
Jul. 5, 2007 (DE) 102007031457.6-45

(51) Int. Cl. C23C 16/30; C23C 16/44

(52) U.S. Cl. 427/255.6; 118/719

(57) ABSTRACT

During the process for applying a coating of separating agent to a moving or movable substrate in a vacuum chamber, wherein the separating agent is vaporized in the interior of a vaporizing chamber that contains at least one nozzle pointing towards the substrate, liquid separating agent is injected into the interior of the vaporizing chamber to be vaporized. The necessary apparatus for applying a coating of separating agent to a moving or movable substrate in a vacuum chamber, wherein the vacuum chamber contains at least one metal vaporizing apparatus with a vaporizing chamber that contains a nozzle pointing towards the substrate, wherein the separating agent can be supplied to the interior of the vaporizing chamber via a supply pipe, includes that the supply pipe is connected to an injection apparatus, via which the liquid separating agent is or can be injected into the interior of the vaporizing chamber in order to be vaporized.

The invention relates to a process and apparatus for applying a coating of separating agent to a moving or movable substrate in a vacuum chamber, wherein the separating agent in the interior of a vacuum chamber with at least one nozzle pointing at the substrate will be vaporized or is vaporizable.

The moving or movable substrate is generally a ribbon shaped substrate that will be coated with a metal layer in the vacuum chamber of a coating unit. In the course of the coating process the substrate will be directed past a metal coating apparatus, and it will be wound over rollers from an unwind roller to a take-up roller.

The separating agent generally could be an ester, glycol, fluorinated hydrocarbon or hydrocarbon. The preferred separating agent is perfluoropolyether oil. Areas of the substrate that are not to be coated with metal, so-called free slots, will be covered with separating agent mask.

This separating agent can be inserted into the interior of the vaporizing chamber for said separating agent through a supply pipe. The vaporizer has a nozzle or nozzle band that is pointed at the substrate, and which connects the vacuum chamber to the vaporizing chamber.

The separating agent is vaporized in a low vacuum in the interior of the vaporizing chamber and is often applied to the substrate inside the vacuum chamber through the nozzle after the vaporization phase but just before the coating phase to produce a free slot.

When applying the separating agent to the substrate it is important to regulate the amount of separating agent in such a way that only the necessary amount of oil will be vaporized to create an optimized masking, and that separating agent is only vaporized if it is required for the application.

It is known, for example from EP 1 035 553 A1, that one or more heatable blocks heated to a temperature greater than the boiling point of oil are used for vaporizing oil. Because of the dimensions of the blocks the replenishment of oil through a change in temperature of the separating agent that is to be vaporized is not possible at all or fast enough, even if the substrate speeds vary.

Valves should be used to stop the separating agent from unnecessarily entering into the vacuum chamber during the initial and final phases of the substrate coating and contaminating it. Through these valves the vaporized separating agent is blocked from entering the nozzle band. But the vaporized separating agent will be able to enter through different routes into the vacuum chamber and contaminate it because generally vent notches must be provided.

Currently all vaporizers of separating agents heat up large amounts of separating agent in a vat, but only a small amount is vaporized during a coating process of the equipment. The rest that is not vaporized will be reused up to the point where low volatile particles and decomposition products make any further use impossible and necessitate cleaning of the vaporizer. The disadvantage is that the properties of the separating agent can change slowly and in an uncontrolled manner during the lifespan of the separating agent due to the enrichment of the low volatile particles and the decomposition products. Furthermore, a pool of separating agent that needs to be disposed of is formed and could cause extra costs and damages to the environment.

This invention is meant to create a process and the apparatus for applying a coating of separating agent to a moved or movable substrate in a vacuum chamber that will improve the prior art technology.

This task is achieved through the features of the independent patent claims.

It is intended that the liquid separating agent will be injected into the interior of the vacuum chamber for vaporization during the process according to the invention of the application for applying a coating of separating agent to a moving or movable substrate in a vacuum chamber, wherein the separating agent in the interior of a vacuum chamber with at least one nozzle pointing at the substrate will be vaporized. Unlike in other processes, in the process of the invention the separating agent will not be vaporized through a metal block or a solution, but will be vaporized during or straight after the injection of a specified amount into the interior of the vaporizing chamber. Therefore the problem of heat inertia of a metal block is eliminated.

Furthermore, the problem of a change in the properties of the separating agent through distillation over a long period of time is eliminated because there is no bath for separating agents. No separating agents are wasted by disposal of the pool, therefore costs will be kept low.

According to a preferred embodiment of the invention, the amount of separating agent that is to be injected depends on the given thickness of the coating of separating agent which corresponds to the given speed of the substrate, so that an unnecessary vaporization of separating agent is avoided, and a vaporization of separating agent in the vacuum chamber is minimized or at least reduced. The injection process also permits a delay-free or less delayed start and/or stop of the application of separating agent or masking of the substrate because only a small amount of separating agent is fed into the interior of the vaporizing chamber and can be vaporized relatively quickly. A delay-free or less delayed start and/or stop of the masking process eliminates a carryover of separating agent to many transport elements, e.g. rollers which causes a decline in the quality of the coating. The injection of separating agent for vaporization in the interior chamber that is suggested in this invention allows for a better or even delay-free regulation of the amount of separating agent that is applied to the substrate according to the various speeds of the moving or movable substrate and guarantees a constant product quality.

According to another form of the invention the separating agent is introduced via a supply pipe from a reservoir. It is especially preferred when the reservoir is exposed to atmospheric pressure so that the filling of the reservoir does not require any special filling equipment and is kept fairly simple.

The supply of separating agent into the vaporizing chamber takes place under a higher pressure than the pressure in the vacuum chamber, so that the transportation of the vaporized separating agent from the interior of the vaporizing chamber through the nozzle or nozzles to the substrate happens a lot faster because of the difference in pressure.

A pump or more specifically a volumetric pump should be used to allow for a controlled injection of the separating agent.

According to another variation of the invention, a flash vaporization of the separating agent occurs, wherein the separating agent is completely vaporized straight after it is injected into the interior of the vaporizing chamber. Especially during the vaporization process, no liquid separating agent or only small amounts of it are located in the vaporizing chamber.

At least some parts of the walls of the vaporizing chambers are kept at a temperature that is clearly higher than the boiling point of the separating agent in vacuum, so that a faster and complete vaporization of the injected amount of separating agent can be guaranteed. The vaporization of the separating agent can be controlled more easily when the temperature of these chamber walls is preferably kept constant.

It is also advantageous if other components that come into contact with the liquid or vaporized separating agent are heated up to a temperature that is higher than the boiling point of the separating agent, e.g. 100° C. Preferably, the nozzle should be heated up to this temperature as well.

The fast and complete vaporization of the quantity of separating agent that is injected into the interior can be achieved more easily if the separating agent is injected to a heated vaporizing surface in the interior of the vaporizing chamber. It is even better if the vaporizing surface can be heated separately from the chamber walls because the heat inertia of the vaporization surface is lower than that of the chamber walls, so the temperature can be changed faster. The amount of oil that is vaporized is controlled through the amount of oil that is injected. It is of advantage to heat the vaporization plate separately because heating of the entire oven to high temperatures such as 200° C. can cause deformation and security risks.

In another form of the invention the injection is regulated through an excess pressure valve which means the pressure in the supply pipe can be kept at a level slightly higher than the atmospheric pressure so that an evaporation of separating agent in the supply line can be prevented. The excess pressure valve should be heatable and heated. The excess pressure valve should have a counter pressure of at least 1 bar, so that no oil is pushed past the pump into the chamber once the chamber is empty.

In another form of the invention, an opening of the nozzles on the interior side is protected through a labyrinth plate from the area into which the separating agent is being injected, so that a more homogeneous vapor is supplied to the nozzles and no splash reaches the foil.

The supply pipe in the apparatus described in the invention is connected to the injection equipment that is or can be used to inject the liquid separating agent into the interior of the vaporizing chamber so it can be vaporized to apply a coating of separating agent to a moving or movable substrate in a vacuum chamber, wherein the vacuum chamber has at least one metal vaporizing apparatus with a vaporizing chamber, which contains at least one nozzle pointing at the substrate, and wherein the separating agent can be supplied to the interior of the vaporizing chamber through a supply pipe.

Other features and forms of the inventions and their advantages can be found in the description of an embodiment below, independently of their summary of patent claims, with reference to a drawing.

The following is illustrated:

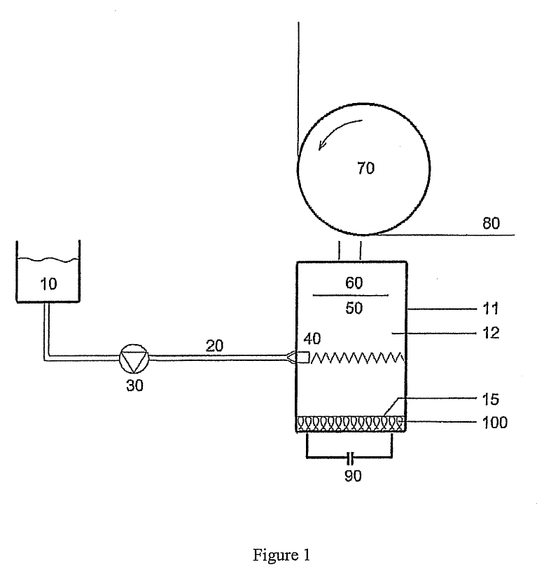

FIG. 1A schematic diagram of the apparatus of the invention that is used to apply a coating of separating agent to a moving or movable substrate in a vacuum chamber.

The vaporizing chamber 11 with an interior 12 with corresponding walls without any reference numerals in FIG. 1 has a nozzle 60 which points to a moving ribbon-shaped substrate 80. The nozzle 60 has an opening pointing to the interior where the vaporized or vaporous separating agent is transported to areas of the substrate 80. The substrate 80 will be transported on a roller 70 through a vacuum chamber that contains coating equipment with a metal vaporizer that is not illustrated in the drawing, wherein the direction of rotation of the roller 70 is indicated by an arrow. Preferably, but not exclusively, a coating of aluminium is applied.

The interior 12 of the vaporizing chamber 11 contains a vaporizing plate 15 that is heated by a heatable heat appliance 100 that can be powered, for example, via a power supply unit 90. In addition the walls of the interior 12 are heatable. Preferably the nozzle 60 should be located geodetically higher than the vaporizing plate 15.

The vaporizing chamber 11 is connected to a reservoir 10 for separating agent through a supply pipe 20, where the separating agent could be esters, glycols, fluorinated hydrocarbons or hydrocarbons. Perfluoropolyether oil is preferred. Separating agent in the reservoir 10 can be under atmospheric pressure. A pump 30 is located in the supply pipe 20 to transport the separating agent in the vaporizing chamber 11. The pump 30 could be a volumetric pump to regulate the dosage of the separating agent that is to be supplied to the vaporizing chamber 11. An injection apparatus 40 is located right next to the supply pipe 20 on the interior 12 of the vaporizing chamber 11. Preferably the injection apparatus 40 should come in the shape of an excess pressure valve. To avoid gas emissions of separating agent into the supply pipe 20 the separating agent should preferably be transported to the vaporizing chamber 11 under pressure that is higher than atmospheric pressure. The excess pressure valve 40 is located geodetically higher than the vaporizing plate 15 and lower than the nozzle 60.

During operation of the device of the invention, liquid separating agent is injected into the vaporization chamber for vaporization via the injection apparatus 40. Injection should preferably occur to the vaporization plate 15 or at least in the direction of the vaporization plate 15.

A relatively low vacuum should be kept in the vaporization chamber 11, e.g. 15 mbar, and the vacuum in the vacuum chamber should typically be higher, e.g. 10⁻³ mbar. At least parts of the walls of the interior 12 of the vaporizer chamber 11 should be kept at a temperature that is much higher than the boiling point of the separating agent in this vacuum. Preferably all parts of the vaporizer are hotter than the boiling point, otherwise the separating agent will condense out in the vaporizer. The vaporizing plate 15 should also be kept at a higher temperature than the boiling temperature of the separating agent.

A labyrinth plate 50 is fitted for protection of the opening on the interior side of the nozzle 60 to increase the homogeneity of the separating agent that is transported via the nozzle 60, and is located above the interior 12 where the liquid separating agent is vaporized.

During operation of the apparatus of the invention, a quantity of separating agent from the reservoir 10 will be transported through the volumetric pump 30 into vaporizing chamber 11 and injected through valve 40 into the interior 12. Typically the volume of interior 12 is between 0.5 and 5 l. A typical volume flow of injected separating agent is 0.2 ml/min to 5 ml/min.

The injected amount of separating agent vaporizes very fast and nearly completely. Preferably flash vaporization is used where the injected amount of separating agent vaporizes immediately and completely. Afterwards the vaporized separating agent will be transported to the nozzle 60 to be applied to the substrate 80 as masking.

1. Method for applying a coating of separating agent to a moving or movable substrate in a vacuum chamber, comprising:
vaporizing the separating agent in the interior of a vaporizing chamber that has at least one nozzle pointing at the substrate; and
injecting the liquid separating agent into the vaporizing chamber for vaporization.

2. Method according to claim 1, wherein an amount of separating agent is injected that corresponds to a thickness of the coating of separating agent that is needed for a corresponding speed of a substrate.

3. Method according to claim 1, wherein the separating agent will be supplied via a supply line from a reservoir that has a pressure that is preferably lower than atmospheric pressure.

4. Method according to claim 1, wherein transportation to the vaporizing chamber takes place under pressure that is higher than atmospheric pressure.

5. Method according to claim 1, wherein flash vaporizing is used to vaporize the separating agent.

6. Method according to claim 1, wherein the injection of separating agent is started at a beginning of movement of the substrate and stopped at an end of the movement of the substrate.

7. Method according to claim 1, wherein an amount of separating agent that is injected is regulated according to a speed of the substrate.

8. Method according to claim, wherein supply is regulated through a volumetric pump.

9. Method according to claim 1, wherein a heatable excess pressure valve is used for injection.

10. Method according to claim 1, wherein the interior of the vaporizing chamber is emptied during one operating stage.

11. Method according to claim 1, wherein walls of the interior and/or the nozzle are heated to a temperature higher than a boiling temperature of the separating agent.

12. Method according to claim 1, wherein a difference in pressure between the interior and the vacuum chamber is maintained during an operating stage in the vaporizing chamber.

13. Method according to claim 1, wherein the separating agent is injected to a heated surface in the interior, the heated surface comprising a surface that is not attached to any of the walls.

14. Method according to claim 1, wherein the opening of the nozzle that points towards the interior and is situated opposite the area in which the separating agent is injected is covered by a labyrinth plate.

15. Apparatus for applying a coating of separating agent to a moving or movable substrate in a vacuum chamber, wherein the vacuum chamber contains at least one metal vaporizing apparatus with a vaporizing chamber that has at least one nozzle pointing at the substrate, wherein separating agent can be supplied to the vaporizing chamber through a supply pipe, wherein the supply pipe is connected to an injection apparatus, via which the liquid separating agent can be or is injected into the interior of the vaporizer chamber for vaporization.

16. Apparatus according to claim 15, wherein the injection apparatus contains a heatable excess pressure valve.

17. Apparatus according to claim 15, wherein the supply pipe is connected to a volumetric pump.

18. Apparatus according to claim 15, wherein a heatable vaporizing area that preferably is not attached to any chamber walls is situated in the interior of the vaporizing chamber.

19. Apparatus according to claim 15, wherein the excess pressure valve is situated geodetically above the vaporizing area.

20. Apparatus according to claim 15, wherein the nozzle has an opening that is situated geodetically above the excess pressure valve pointing towards the interior.

21. Apparatus according to claim 20, wherein a labyrinth plate is situated in the interior of the vaporizer chamber, geodetically above the excess pressure valve and geodetically below the nozzle opening that points toward the interior.

22. Apparatus according to claim 15, wherein the supply pipe is connected to a reservoir for the separating agent.
